(19) United States
(12) Patent Application Publication
(10) Pub. No.: US 2025/0322875 A1
(43) Pub. Date: Oct. 16, 2025

(54) OPERATION PULSE SIGNAL CONTROL METHOD FOR NON-VOLATILE MEMORY CELL

(71) Applicant: eMemory Technology Inc., Hsin-Chu (TW)

(72) Inventor: I-Lang LIN, Hsinchu County (TW)

(21) Appl. No.: 19/089,031

(22) Filed: Mar. 25, 2025

Related U.S. Application Data
(60) Provisional application No. 63/632,599, filed on Apr. 11, 2024.

(51) Int. Cl. G11C 16/04; G11C 16/10; G11C 16/14; G11C 16/34

(52) U.S. Cl. CPC G11C 16/0441; G11C 16/10; G11C 16/14; G11C 16/3436

(57) ABSTRACT

An operation pulse signal control method is provided. In a step (a), a verification action is performed to obtain a first sub-state value of a memory cell. In a step (b), a pulse of an operation pulse signal is provided to the memory cell. In a step (c), the verification action is performed to obtain a second sub-state value of the memory cell. If the second sub-state value indicates that the memory cell has not reached a target storage state, an actual difference value is defined as the second sub-state value minus the first sub-state value, a next pulse is adjusted according to the actual difference value, the first sub-state value is set to the second sub-state value, and the step (b) is performed again. If the memory cell has reached the target storage state, the next pulse is not provided.

This application claims the benefit of U.S. provisional application Ser. No. 63/632,599, filed Apr. 11, 2024, the subject matters of which is incorporated herein by reference.

### FIELD OF THE INVENTION

The present invention relates to a control method for a non-volatile memory cell, and more particularly to an operation pulse signal control method when a program action or an erase action is performed on a non-volatile memory cell.

### BACKGROUND OF THE INVENTION

Non-volatile memories have been widely used in a variety of electronic products. After the supplied power is interrupted, the data stored in the non-volatile memory is still retained. The non-volatile memory comprises plural non-volatile memory cells. The plural non-volatile memory cells are arranged in an array structure. Each non-volatile memory cell comprises a floating gate transistor.

According to the number of times the non-volatile memory cell is programmed, the non-volatile memory cells may be classified into a multi-time programming memory cell (also referred as a MTP memory cell) or a one time programming memory cell (also referred as an OTP memory cell). By providing proper bias voltages to the array structure, a program action, a read action or a read operation can be selectively performed on any non-volatile memory cell of the array structure.

### SUMMARY OF THE INVENTION

An embodiment of the present invention provides an operation pulse signal control method for a non-volatile memory cell. The memory cell has plural sub-states. The operation pulse signal control method includes the following steps. In a step (a), a verification action is performed to obtain a first sub-state value of the memory cell. In a step (b), a pulse of an operation pulse signal is provided to the memory cell. In a step (c), the verification action is performed to obtain a second sub-state value of the memory cell. If the second sub-state value indicates that the memory cell has not reached a target storage state, an actual difference value is defined as the second sub-state value minus the first sub-state value, a next pulse is adjusted according to the actual difference value, the first sub-state value is set to be equal to the second sub-state value, and the step (b) is performed again. If the second sub-state value indicates that the memory cell has reached the target storage state, the next pulse is not provided.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A is a schematic circuit diagram illustrating a non-volatile memory cell according to an embodiment of the present invention;

FIG. 1B is a schematic circuit diagram illustrating the bias voltages provided to the memory cell when the program action is performed on the memory cell;

FIG. 1C is a schematic circuit diagram illustrating the bias voltages provided to the memory cell when the erase action is performed on the memory cell;

FIGS. 1D and 1E are schematic circuit diagrams illustrating the bias voltages provided to the memory cell when a read action is performed on the memory cell;

FIG. 1F is a schematic circuit diagram illustrating a current comparator in a sensing circuit;

FIG. 2A is a schematic circuit block diagram illustrating the architecture of an operation pulse generator;

FIG. 2B is a lookup table about the relationship between the pulse heights and the multiple values of the pulses in the operation pulse signal;

FIG. 2C is a schematic waveform diagram illustrating the operation pulse signal generated by the operation pulse generator;

FIG. 3A schematically illustrates a memory cell sub-state classification table for a program action;

FIG. 3B schematically illustrates a memory cell sub-state classification table for an erase action;

FIG. 3C is a flowchart of an operation pulse signal control method when an erase action is performed;

FIG. 4A is a schematic circuit block diagram illustrating the architecture of an operation pulse generator according to another embodiment of the present invention;

FIG. 4B schematically illustrates an implementation example of adjusting the pulse height of the operation pulse signal by using the operation pulse generator and the operation pulse signal control method of the present invention;

FIG. 4C schematically illustrates an implementation example of performing the pulse adjustment step S458 of FIG. 4B to adjust the pulse height;

FIG. 4D is a schematic timing waveform diagram of the operation pulse signal to describe the implementation of the flowcharts of FIGS. 4B and 4C;

FIG. 5A schematically illustrates another implementation example of performing the pulse adjustment step S458 of FIG. 4B to adjust the pulse height;

FIG. 5B is a schematic timing waveform diagram of the operation pulse signal to describe an implementation example of the flowcharts of FIGS. 4B and 5A; and

FIG. 5C is a schematic timing waveform diagram of the operation pulse signal to describe another implementation example of the flowcharts of FIGS. 4B and 5A.

### DETAILED DESCRIPTION OF PREFERRED EMBODIMENTS

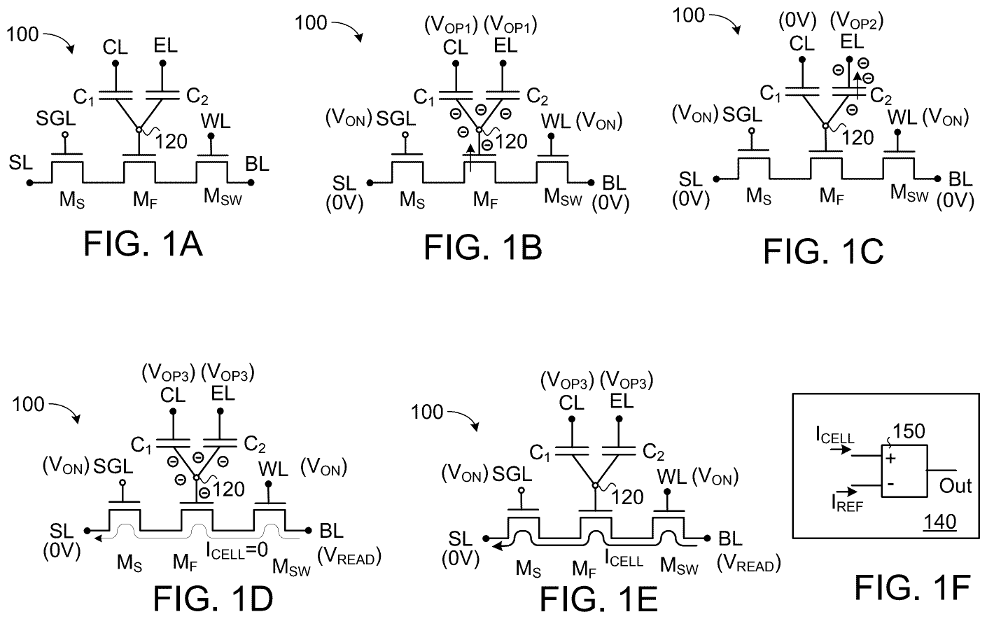

FIG. 1A is a schematic circuit diagram illustrating a non-volatile memory cell according to an embodiment of the present invention. For illustration, the non-volatile memory cell may be referred hereinafter as a memory cell. The memory cell 100 includes a switch transistor M_{SW}, a select transistor M_{S}, a floating gate transistor M_{F}, a capacitor C₁ and a capacitor C₂. Since the memory cell 100 includes three transistors and two capacitors, the memory cell 100 may be referred as a 3T2C memory cell. The switch transistor M_{SW}, the select transistor M_{S} and the floating gate transistor M_{F} of the memory cell 100 are n-type transistors. In addition, the memory cell 100 is an MTP memory cell. Alternatively, the transistors of the memory cell 100 are p-type transistors.

The first source/drain terminal of the select transistor M_{S} is connected to a source line SL. The gate terminal of the select transistor M_{S} is connected to a select gate line SGL. The first source/drain terminal of the floating gate transistor M_{F} is connected to the second source/drain terminal of the select transistor M_{S}. The first source/drain terminal of the switch transistor M_{SW} is connected to the second source/drain terminal of the floating gate transistor M_{F}. The second source/drain terminal of the switch transistor M_{SW} is connected to a bit line BL. The gate terminal of the switch transistor M_{SW} is connected to a word line WL. The first terminal of the first capacitor C₁ is connected to a floating gate 120 of the floating gate transistor M_{F}. The second terminal of the first capacitor C₁ is connected to a control line CL. The first terminal of the second capacitor C₂ is connected to the floating gate 120 of the floating gate transistor M_{F}. The second terminal of the capacitor C₂ is connected to an erase line EL.

Generally, by providing proper bias voltages to the memory cell 100, the memory cell 100 can be selectively programmed, erased, or read. FIG. 1B is a schematic circuit diagram illustrating the bias voltages provided to the memory cell when the program action is performed on the memory cell. When the program action is performed on the memory cell 100, a first operating voltage V_{OP1} is provided to the control line CL and the erase line EL, a turn-on voltage V_{ON} is provided to the word line WL and the select gate line SGL, and a ground voltage (0V) is provided to the bit line BL and the source line SL. For example, the first operating voltage V_{OP1} is 17V, and the turn-on voltage V_{ON} is 2.0V. The first operating voltage V_{OP1} can also be referred as a program voltage. Generally, during the program action, the highest voltage provided to the memory cell 100 is the program voltage.

Under the bias condition of FIG. 1B, the select transistor M_{S} and the switch transistor M_{SW} are turned on. Meanwhile, a Fowler-Nordheim Tunneling effect (also referred as an FN tunneling effect) occurs inside the memory cell 100, and electrons are injected into the floating gate 120 from the floating gate transistor M_{F}. Consequently, the memory cell 100 is in a programmed state. Generally, after electrons are injected into the floating gate 120, the threshold voltage of the floating gate transistor M_{F} increases. Furthermore, as more electrons are injected into the floating gate 120, the threshold voltage of the floating gate transistor M_{F} increases.

Furthermore, if an off voltage V_{OFF} is provided to the word line WL and the select gate line SGL during the program action, the select transistor M_{S} and the switch transistor M_{SW} are turned off. Meanwhile, the FN tunneling effect does not occur, and electrons cannot be injected into the floating gate 120. Consequently, the storage state of the memory cell 100 remains unchanged. For example, the off voltage V_{OFF} is 0V.

FIG. 1C is a schematic circuit diagram illustrating the bias voltages provided to the memory cell when the erase action is performed on the memory cell. When the erase action is performed on the memory cell 100, a second operating voltage V_{OP2} is provided to the erase line EL, the turn-on voltage V_{ON} is provided to the word line WL and the select gate line SGL, and the ground voltage (0V) is provided to the control line CL, the bit line BL and the source line SL. For example, the second operating voltage V_{OP2} is 19V, and the second operating voltage V_{OP2} can also be referred as an erase voltage. Generally, during the erase action, the highest voltage provided to the memory cell 100 is the erase voltage.

Under the bias condition of FIG. 1C, the memory cell 100 undergoes the FN tunneling effect, and electrons are ejected from the floating gate 120 to the erase line EL through the second capacitor C₂. Consequently, the memory cell 100 is in an erased state. Similarly, when electrons are ejected from the floating gate 120, the threshold voltage of the floating gate transistor M_{F} decreases. Furthermore, as more electrons are ejected from the floating gate 120, the threshold voltage of the floating gate transistor M_{F} decreases.

FIGS. 1D and 1E are schematic circuit diagrams illustrating the bias voltages provided to the memory cell when a read action is performed on the memory cell. FIG. 1F is a schematic circuit diagram illustrating a current comparator in a sensing circuit.

Please refer to FIGS. 1D and 1E. When the read action is performed on the memory cell 100, a third operating voltage V_{OP3} is provided to the erase line EL and the control line CL, the turn-on voltage V_{ON} is provided to the word line WL and the select gate line SGL, a read voltage V_{READ} is provided to the bit line BL, and the ground voltage (0V) is provided to the source line SL. For example, the read voltage V_{READ} is in the range between 0V and 2V, and the third operating voltage V_{OP3} is in the range between 0V and 2V.

As shown in FIG. 1D, the memory cell 100 is in the programmed state. Since electrons are stored in the floating gate 120, the threshold voltage of the floating gate transistor M_{F} is higher. Consequently, during the read action, the third operating voltage V_{OP3} is coupled to the floating gate 120 and still unable to turn on the floating gate transistor M_{F}. Under this circumstance, a cell current I_{CELL} generated by the memory cell 100 is nearly equal to zero.

As shown in FIG. 1E, the memory cell 100 is in the erased state. Since no electrons are stored in the floating gate 120, the threshold voltage of the floating gate transistor M_{F} is lower. Consequently, during the read action, the third operating voltage V_{OP3} is coupled to the floating gate 120 to turn on the floating gate transistor M_{F}. Under this circumstance, the memory cell 100 generates a higher cell current I_{CELL}, e.g., 65 μA. The cell current I_{CELL} flows from the bit line BL to the source line SL.

In other words, the magnitudes of the cell current I_{CELL} in different states are different. Consequently, during the read action, the storage state of the memory cell 100 can be determined according to the magnitude of the cell current I_{CELL} generated by the memory cell 100. For example, as shown in FIG. 1F, the non-volatile memory is equipped with a sensing circuit 140. The sensing circuit 140 includes a current comparator 150. A first terminal of the current comparator 150 receives the cell current I_{CELL}. The second terminal of the current comparator 150 receives a reference current I_{REF}. For example, the reference current I_{REF} is 10 μA. In case that the cell current I_{CELL} is higher than the reference current I_{REF}, an output signal Out from the current comparator 150 is in a first logic level state (e.g., in a high logic level state), indicating that the memory cell 100 is in the erased state. Whereas, in case that the cell current I_{CELL} is lower than the reference current I_{REF}, the output signal Out from the current comparator 150 is in a second logic level state (e.g., in a low logic level state), indicating that the memory cell 100 is in the programmed state.

As mentioned above, during the program action of the memory cell 100, the fixed first operating voltage V_{OP1} is provided to the control line CL and the erase line EL. Moreover, during the erase action of the memory cell 100, the fixed second operating voltage V_{OP2} is provided to the erase line EL.

In another embodiment, the non-volatile memory is equipped with an operation pulse generator. The operation pulse generator can provide an operation pulse signal P_{OP} to the memory cell 100 during the program action or the erase action. Hereinafter, the operation pulse signal P_{OP} is used in the erase action of the memory cell 100. Of course, the operation pulse signal P_{OP} can also be used in the program action of the memory cell 100.

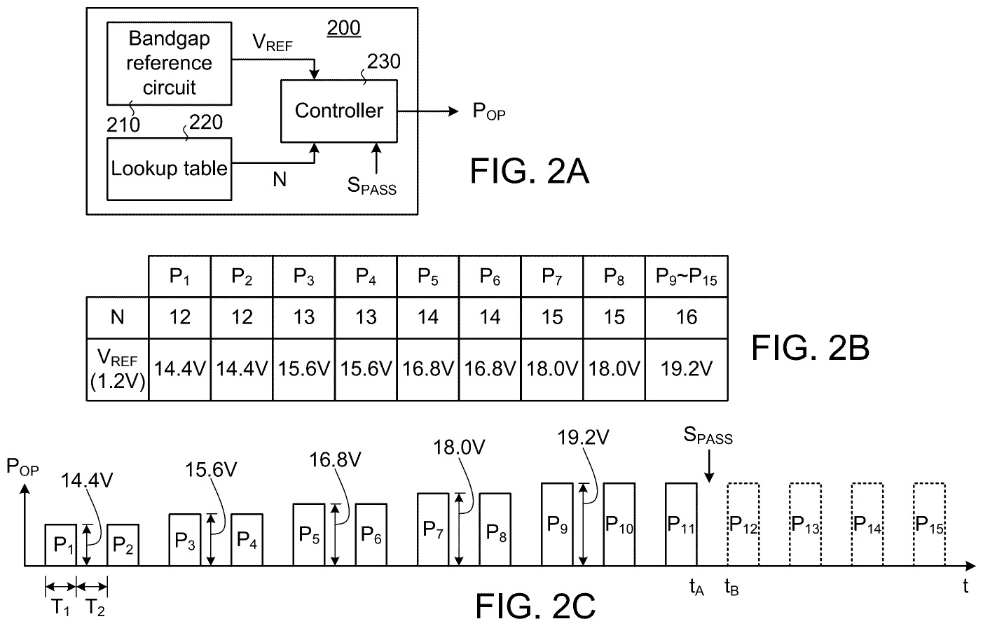

FIG. 2A is a schematic circuit block diagram illustrating the architecture of an operation pulse generator. FIG. 2B is a lookup table about the relationship between the pulse heights and the multiple values of the pulses in the operation pulse signal. FIG. 2C is a schematic waveform diagram illustrating the operation pulse signal generated by the operation pulse generator.

As shown in FIG. 2A, the operation pulse generator 200 includes a bandgap reference circuit 210, a lookup table 220 and a controller 230. The controller 230 receives a reference voltage V_{REF} from the bandgap reference circuit 210. The controller 230 is further connected to the lookup table 220 to receive a multiple value N. The lookup table 220 may be stored in a memory. The multiple value N is a positive number.

The controller 230 can generate the operation pulse signal P_{OP} according to the reference voltage V_{REF} and the multiple value N. For example, the controller 230 includes a charge pump to generate a pulse height of N×V_{REF}. In this embodiment, all pulses P₁˜P₁₅ are set to have the same pulse period and the same pulse width.

For example, the pulse period of the first pulse P₁ is (T₁+T₂), the pulse width of the first pulse P₁ is T₁, and both T₁ and T₂ are 10 ms. In some other embodiments, the pulse period and the pulse width of each pulse can be set according to the practice requirements. For example, the pulse period and the pulse width of each pulse are set in the lookup table 220, and thus the controller 230 generates a corresponding operation pulse signal P_{OP}.

As shown in FIGS. 2B and 2C, the reference voltage V_{REF} is 1.2V, and the operation pulse signal P_{OP} contains at most 15 pulses P₁-P₁₅. In fact, when the erase action is performed, the pulse number of the operation pulse signal P_{OP} may be less than 15.

The relationship between the pulse heights and the multiple values of the pulses in the operation pulse signal can be seen in the lookup table 220. The pulse heights of the first pulse P₁ and the second pulse P₂ generated by the operation pulse generator 200 are 14.4V (12×1.2V). The pulse heights of the third pulse P₃ and the fourth pulse P₄ generated by the operation pulse generator 200 are 15.6V. The pulse heights of the fifth pulse P₅ and the sixth pulse P₆ generated by the operation pulse generator 200 are 16.8V. The pulse heights of the seventh pulse P₇ and the eighth pulse P₈ generated by the operation pulse generator 200 are 18.0V. The pulse heights of the ninth pulse P₉ to the fifteenth pulse P₁₅ generated by the operation pulse generator 200 are 19.2V.

When the erase action is performed, the controller 230 of the operation pulse generator 200 generates a pulse to the memory cell 100. Then, the sensing circuit in the non-volatile memory will immediately perform a verification action to determine whether the memory cell 100 has reached the erased state. If the memory cell 100 has not reached the erased state, the controller 230 continuously generates the next pulse. Whereas, if the memory cell 100 has reached the erased state, the controller 230 receives an activated verification pass signal S_{PASS}, indicating that the erase action is completed. In response to the verification pass signal S_{PASS}, the controller 230 stops generating the next pulse.

Please refer to FIG. 2C. During the time period T₁ of the erase action, the controller 230 of the operation pulse generator 200 generates the first pulse P₁ to the erase line EL of the memory cell 100. Then, a verification action is performed during the time period T₂ of the erase action. Meanwhile, the current comparator 150 of the sensing circuit 140 receives the read current (or cell current) from the memory cell 100 to determine whether the memory cell 100 has reached the erased state. If the memory cell 100 has not reached the erased state, the controller 230 continuously generates the second pulse P₂ to the erase line EL. Whereas, if the memory cell 100 has reached the erased state, it means that the erase action is completed and the controller 230 no longer generates the second pulse P₂. That is, in the time period between two pulses of the operation pulse signal P_{OP}, the sensing circuit 140 performs the verification action. Generally, the method of performing the verification action by the sensing circuit 140 is similar to the method of performing the read action, and not redundantly described herein.

Please refer to FIG. 2C again. After the controller 230 of the operation pulse generator 200 outputs the 11th pulse P₁₁, the verification action is performed in the time interval between the time point TA and the time point T_{B}. In addition, the verification pass signal S_{PASS} is activated, indicating that the erase action is completed. Consequently, the operation pulse generator 200 no longer generates the subsequent four pulses P₁₂-P₁₅. In other words, the erase action is completed in response to the 11 pulses P₁-P₁₁ of the operation pulse signal P_{OP}.

As mentioned above, when the erase action is performed on the memory cell 100, the operation pulse generator 200 provides the operation pulse signal P_{OP} to the erase line EL. Consequently, the memory cell 100 undergoes an FN tunneling effect, and electrons are ejected from the floating gate 120 to the erase line EL through the second capacitor C₂. Under this circumstance, the memory cell 100 is in the erased state.

Similarly, another multiple value N of the operation pulse signal can be set in the lookup table 220 and applied to the program action. According to the same operating principle, the operation pulse generator 200 provides another operation pulse signal P_{OP} to the control line CL and the erase line EL. Consequently, the FN tunneling effect occurs inside the memory cell 100, and electrons are injected from the floating gate transistor M_{F} into the floating gate 120. Under this circumstance, the memory cell 100 is in the programmed state.

When compared with the approach of providing the fixed first operating voltage V_{OP1} and the fixed second operating voltage V_{OP2} to the memory cell 100, the use of the operation pulse signal P_{OP} for performing the program action and the erase action on the memory cell 100 can improve the programming efficiency and the erasing efficiency.

However, during the operation of the operation pulse generator 200, the reference voltage V_{REF} generated by the bandgap reference circuit 210 may be somewhat different, or the bandgap reference circuit 210 may be malfunctioning. In case that the bandgap reference circuit 210 is malfunctioning, the memory cell 100 is possibly damaged, or the problem of causing program failure or erase failure occurs.

Please refer to the lookup table of FIG. 2B. For example, due to certain manufacturing process variations, the reference voltage V_{REF} outputted from the bandgap reference circuit 210 becomes lower, for example, 1.15V. During the erase action, the maximum pulse height of the operation pulse signal P_{OP} is only 18.4V (16×1.15V). The pulse height of the operation pulse signal P_{OP} is not high enough to remove all electrons from the floating gate 120. Consequently, the erase failure occurs. Similarly, during the program action, the pulse height of the operating pulse signal P_{OP} is not high enough. Since the electrons injected into the floating gate 120 are possibly insufficient, the program failure occurs.

For example, due to the process variations, the reference voltage V_{REF} outputted from the bandgap reference circuit 210 becomes higher, for example, 1.30V. During the erase action, the maximum pulse height of the operation pulse signal P_{OP} reaches 20.8V (16×1.30V). Since the pulse height of the operation pulse signal P_{OP} is too high, the voltage stress on the memory cell 100 is too high. Consequently, the possibility of causing damage of the memory cell 100 increases. Similarly, during the program action, the pulse height of the operation pulse signal P_{OP} is too high. Since the voltage stress on the memory cell 100 is too high, the memory cell 100 is possibly damaged.

In order to solve the problems of using the lookup table 220 to generate the operation pulse signal P_{OP}, the present invention provides an operation pulse signal control method for non-volatile memory cells. In accordance with the control method of the present invention, the state change of the memory cell 100 before and after receiving the pulse will be determined, and then the pulse height or the pulse width of the next pulse will be dynamically adjusted according to the state change. The operations of the operation pulse signal control method will be described in more details as follows. Hereinafter, the control method is used in the erase action of the memory cell 100. Of course, the control method can also be used in the program action of the memory cell 100.

As mentioned above, sufficient electrons are stored in the floating gate 120 of the floating gate transistor M_{F} when the memory cell 100 is in the programmed state. Since the threshold voltage is high, it is not easy to turn on the floating gate transistor M_{F}. When the memory cell 100 is in the erased state, no or less electrons are stored in the floating gate 120 of the floating gate transistor M_{F}. Since the threshold voltage is low, it is easy to turn on the floating gate transistor M_{F}. In accordance with a feature of the present invention, there are plural sub-states between the programmed state and the erased state according to the amount of electrons stored in the memory cell 100.

The operations of the read action are similar to those of the verification action. When the verification action is performed, the third operating voltage V_{OP3} is changed. Furthermore, the memory cell is in one of eight sub-states by the sensing circuit according to the cell current I_{CELL}. When the verification action is performed, the methods of providing the bias voltages are similar to those of FIGS. 1D and 1E. The source line SL of the memory cell 100 receives the ground voltage (0V). The bit line BL receives the read voltage V_{READ}. The select gate line SGL and the word line WL receive the turn-on voltage V_{ON}. Moreover, only the third operating voltage V_{OP3} is subjected to the change.

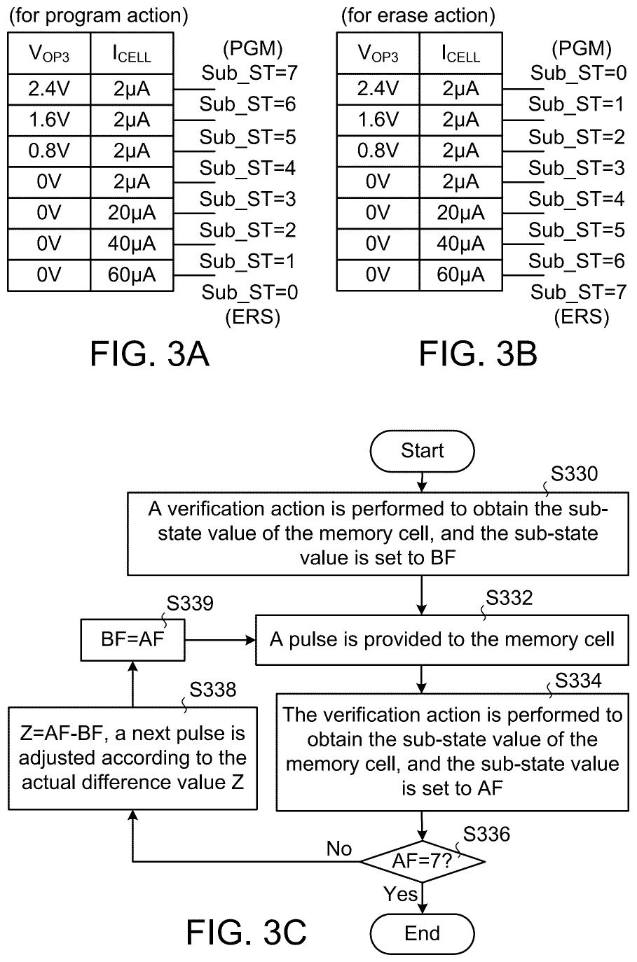

FIG. 3A schematically illustrates a memory cell sub-state classification table for a program action. FIG. 3B schematically illustrates a memory cell sub-state classification table for an erase action.

Please refer to FIG. 3A. If the third operating voltage V_{OP3} is 2.4V and the cell current I_{CELL} generated by the memory cell 100 is lower than 2 μA, the memory cell 100 is classified as the seventh sub-state (Sub_ST=7), and the sub-state value is equal to 7. The memory cell 100 in the seventh sub-state (Sub_ST=7) indicates that the memory cell 100 is in a target storage state, i.e., the programmed state (PGM).

If the third operating voltage V_{OP3} is 2.4V and the cell current I_{CELL} generated by the memory cell 100 is higher than 2 μA and if the third operating voltage V_{OP3} is 1.6V and the cell current I_{CELL} generated by the memory cell 100 is lower than 2 μA, the memory cell 100 is classified as the sixth sub-state (Sub_ST=6), and the sub-state value is equal to 6, which indicates that the memory cell 100 is not in the target storage state.

If the third operating voltage V_{OP3} is 1.6V and the cell current I_{CELL} generated by the memory cell 100 is higher than 2 μA and if the third operating voltage V_{OP3} is 0.8V and the cell current I_{CELL} generated by the memory cell 100 is lower than 2 μA, the memory cell 100 is classified as the fifth sub-state (Sub_ST=5), and the sub-state value is equal to 5, which indicates that the memory cell 100 is not in the target storage state.

If the third operating voltage V_{OP3} is 0.8V and the cell current I_{CELL} generated by the memory cell 100 is higher than 2 μA and if the third operating voltage V_{OP3} is 0V and the cell current I_{CELL} generated by the memory cell 100 is lower than 2 μA, the memory cell 100 is classified as the fourth sub-state (Sub_ST=4), and the sub-state value is equal to 4, which indicates that the memory cell 100 is not in the target storage state.

If the third operating voltage V_{OP3} is 0V and the cell current I_{CELL} generated by the memory cell 100 is higher than 2 μA and lower than 20 μA, the memory cell 100 is classified as the third sub-state (Sub_ST=3), and the sub-state value is equal to 3, which indicates that the memory cell 100 is not in the target storage state.

If the third operating voltage V_{OP3} is 0V and the cell current I_{CELL} generated by the memory cell 100 is higher than 20 μA and lower than 40 μA, the memory cell 100 is classified as the second sub-state (Sub_ST=2), and the sub-state value is equal to 2, which indicates that the memory cell 100 is not in the target storage state.

If the third operating voltage V_{OP3} is 0V and the cell current I_{CELL} generated by the memory cell 100 is higher than 40 μA and lower than 60 μA, the memory cell 100 is classified as the first sub-state (Sub_ST=1), and the sub-state value is equal to 1, which indicates that the memory cell 100 is not in the target storage state.

If the third operating voltage V_{OP3} is 0V and the cell current I_{CELL} generated by the memory cell 100 is higher than 60 μA, the memory cell 100 is classified as the zeroth sub-state (Sub_ST=0), and the sub-state value is equal to 0. The memory cell 100 in the zeroth sub-state (Sub_ST=0) indicates that the memory cell 100 is in the erased state (ERS), which indicates that the memory cell 100 is not in the target storage state.

That is, when the verification action is performed, the sub-state of the memory cell can be judged according to the third operating voltage and the cell current of the memory cell.

The memory cell sub-state classification table for the erase action (in FIG. 3B) is similar to the memory cell sub-state classification table for the program action (in FIG. 3A). For succinctness, only the distinguished parts will be described as follows.

Please refer to FIG. 3B, in this embodiment, a target storage state is the erase state. If the third operating voltage V_{OP3} is 2.4V and the cell current I_{CELL} generated by the memory cell 100 is lower than 2 μA, the memory cell 100 is classified as the zeroth sub-state (Sub_ST=0), and the sub-state value is equal to 0. The memory cell 100 in the zeroth sub-state (Sub_ST=0) indicates that the memory cell 100 is in the programmed state (PGM).

If the third operating voltage V_{OP3} is 2.4V and the cell current I_{CELL} generated by the memory cell 100 is higher than 2 μA and if the third operating voltage V_{OP3} is 1.6V and the cell current I_{CELL} generated by the memory cell 100 is lower than 2 μA, the memory cell 100 is classified as the first sub-state (Sub_ST=1), and the sub-state value is equal to 1, which indicates that the memory cell 100 is not in the target storage state.

If the third operating voltage V_{OP3} is 1.6V and the cell current I_{CELL} generated by the memory cell 100 is higher than 2 μA and if the third operating voltage V_{OP3} is 0.8V and the cell current I_{CELL} generated by the memory cell 100 is lower than 2 μA, the memory cell 100 is classified as the second sub-state (Sub_ST=2), and the sub-state value is equal to 2, which indicates that the memory cell 100 is not in the target storage state.

If the third operating voltage V_{OP3} is 0.8V and the cell current I_{CELL} generated by the memory cell 100 is higher than 2 μA and if the third operating voltage V_{OP3} is 0V and the cell current I_{CELL} generated by the memory cell 100 is lower than 2 μA, the memory cell 100 is classified as the third sub-state (Sub_ST=3), and the sub-state value is equal to 3, which indicates that the memory cell 100 is not in the target storage state.

If the third operating voltage V_{OP3} is 0V and the cell current I_{CELL} generated by the memory cell 100 is higher than 2 μA and lower than 20 μA, the memory cell 100 is classified as the fourth sub-state (Sub_ST=4), and the sub-state value is equal to 4, which indicates that the memory cell 100 is not in the target storage state.

If the third operating voltage V_{OP3} is 0V and the cell current I_{CELL} generated by the memory cell 100 is higher than 20 μA and lower than 40 μA, the memory cell 100 is classified as the fifth sub-state (Sub_ST=5), and the sub-state value is equal to 5, which indicates that the memory cell 100 is not in the target storage state.

If the third operating voltage V_{OP3} is 0V and the cell current I_{CELL} generated by the memory cell 100 is higher than 40 μA and lower than 60 μA, the memory cell 100 is classified as the sixth sub-state (Sub_ST=6), and the sub-state value is equal to 6, which indicates that the memory cell 100 is not in the target storage state.

If the third operating voltage V_{OP3} is 0V and the cell current I_{CELL} generated by the memory cell 100 is higher than 60 μA, the memory cell 100 is classified as the seventh sub-state (Sub_ST=7), and the sub-state value is equal to 7. The memory cell 100 in the zeroth sub-state (Sub_ST=0) indicates that the memory cell 100 is in the target storage state, i.e., the erased state (ERS).

FIG. 3C is a flowchart of an operation pulse signal control method when an erase action or a program action. When the erase action is performed, the target storage state is the erase state. After the erase action is started, a verification action is performed to obtain the sub-state value of the memory cell 100, and the sub-state value is set to BF (Step S330) as an initialization operation. In other words, the value stored in BF is the sub-state value of the memory cell 100 before the pulse is provided. Then, a pulse is provided to the memory cell 100 (step S332). Then, the verification action is performed to obtain the sub-state value of the memory cell 100, and the sub-state value is set to AF (Step S334). In other words, the value stored in AF is the sub-state value of the memory cell 100 after the pulse is provided.

Then, a step S336 is performed to judge whether AF is equal to 7. That is, the step S336 is used to determine whether the memory cell 100 has reached the target storage state (i.e., the erased state). If AF is equal to 7, it means that the memory cell 100 has reached the target storage state (i.e., the erased state). Consequently, it is confirmed that the erase action is completed, and the erase action is ended.

Whereas, if AF is not equal to 7, it means that the memory cell 100 has not reached the target storage state (i.e., the erased state). Meanwhile, the difference between AF and BF (i.e., AF-BF) is defined as an actual difference value Z, and a next pulse is adjusted according to the actual difference value Z (step S338). Then, BF is set to be equal to AF (Step S339), and step S332 is repeatedly done. In this embodiment, the actual difference value Z represents the difference between the sub-states before and after the memory cell 100 receives a pulse. In addition, when the next pulse is adjusted according to the actual difference value Z, the pulse height (N) and the pulse width of the next pulse can be adjusted at the same time. Of course, in some other embodiments, only one of the pulse height and the pulse width of the next pulse is adjusted.

For example, in case that the actual difference value Z is greater than or equal to 3, the actual difference value Z is relatively large. It means that the change of the sub-state of the memory cell 100 in response to the pulse is larger. Consequently, the pulse height or the pulse width of the next pulse can be decreased. In case that the actual difference value Z is less than or equal to 2, the actual difference value Z is relatively small. It means that the change of the sub-state of the memory cell 100 in response to the pulse is smaller. Consequently, the pulse height or the pulse width of the next pulse can be increased, or the pulse height or the pulse width of the next pulse can be maintained.

Similarly, the operation pulse signal control method of FIG. 3C can be applied to the situation when the program action is performed, and the target storage state is the program state. The detailed operations will not be redundantly described herein.

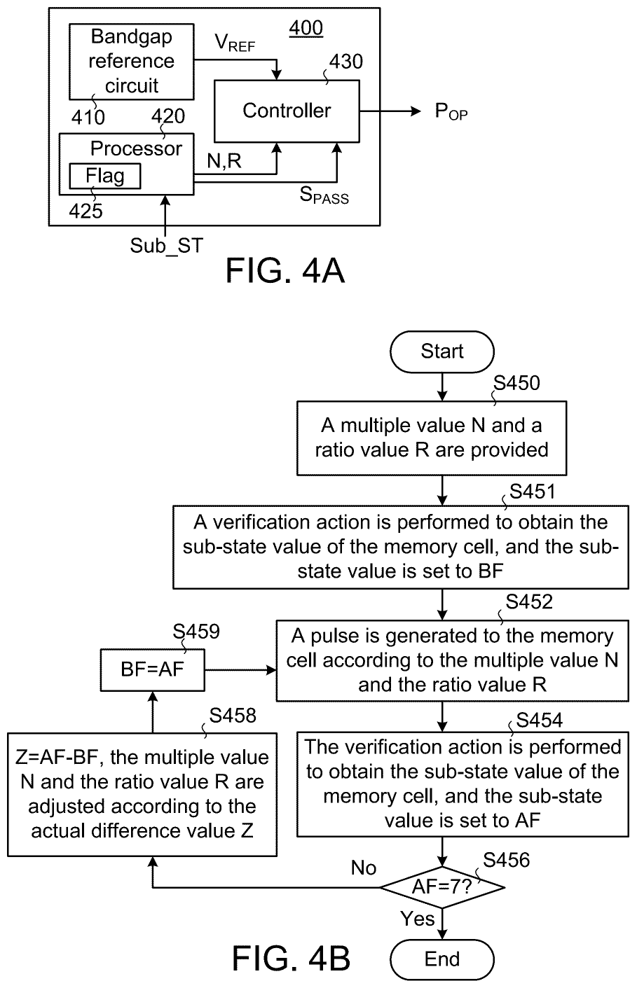

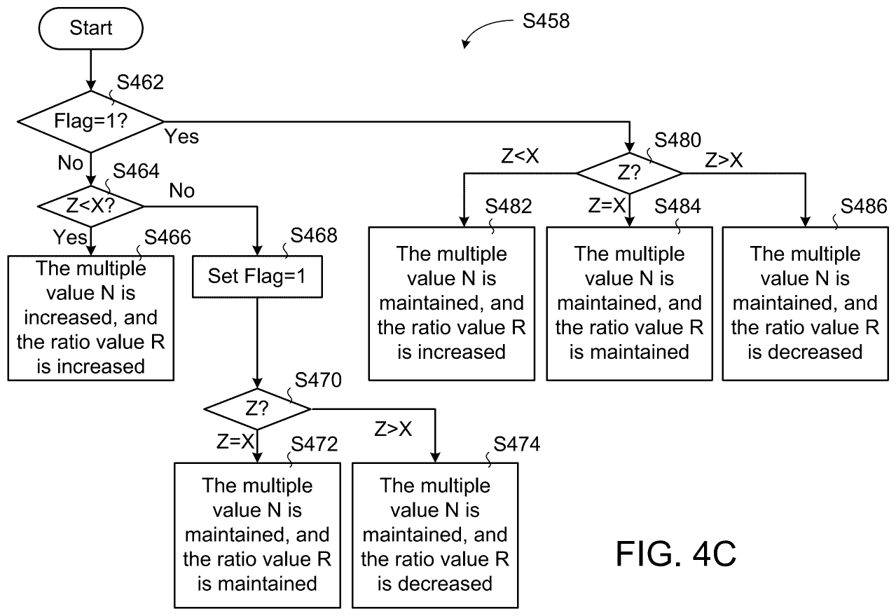

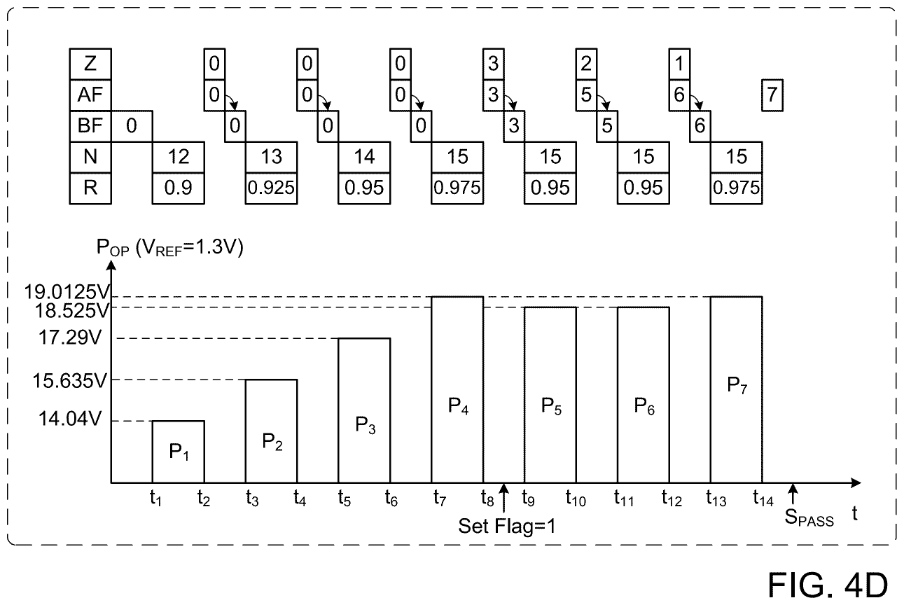

Hereinafter, an implementation example of adjusting the pulse height of the operation pulse signal P_{OP} by using the operation pulse generator and the operation pulse signal control method will be described. This implementation example is applied to the situation when the erase action is performed. FIG. 4A is a schematic circuit block diagram illustrating the architecture of an operation pulse generator according to another embodiment of the present invention. FIG. 4B schematically illustrates an implementation example of adjusting the pulse height of the operation pulse signal by using the operation pulse generator and the operation pulse signal control method of the present invention.

As shown in FIG. 4A, the operation pulse generator 400 includes a bandgap reference circuit 410, a processor 420 and a controller 430. The controller 430 receives a reference voltage V_{REF} from the bandgap reference circuit 410. The processor 420 receives a sub-state signal Sub_ST to determine the sub-state value of the memory cell 100. In addition, the processor 420 generates a multiple value N and a ratio value R to the controller 430. In other words, during the verification action, the processing circuit 420 can receive the sub-state signal Sub_ST from the sensing circuit 140 (see FIG. 1F) to confirm the sub-state of the memory cell 100. In an embodiment, the processor 420 further includes a flag register 425.

The controller 430 generates the operation pulse signal P_{OP} according to the reference voltage V_{REF}, the multiple value N and the ratio value R. For example, the controller 430 includes a charge pump that can generate a pulse height of (N×R×V_{REF}). In addition, when the sub-state signal Sub_ST is equal to the target storage state, the processor 420 can activate the verification pass signal S_{PASS}. In response to the verification pass signal S_{PASS}, the controller 430 stops generating the next pulse.

Please refer to FIG. 4B. After the erase action is started, the processor 420 provides an initial multiple value N and an initial ratio value R (Step S450). Then, a verification action is performed to obtain the sub-state value of the memory cell 100, and the sub-state value is set to BF (Step S451). Of course, the step S450 and the step S451 can be swapped.

Then, the controller 430 generates a pulse to the memory cell 100 according to the multiple value N and the ratio value R (step S452). Then, the verification action is performed to obtain the sub-state value of the memory cell 100, and the sub-state value is set to AF (Step S454).

Then, a step S456 is performed to judge whether AF is equal to 7. That is, the step S456 is used to determine whether the memory cell 100 has reached the target storage state (i.e., the erased state). If AF is equal to 7, it means that the memory cell 100 has reached the target storage state (i.e., the erased state). Consequently, the processor 420 activates the verification pass signal S_{PASS} to indicate that the erase action is completed. Then, the controller 430 stops generating the next pulse and ends the erase action.

Whereas, if AF is not equal to 7, it means that the memory cell 100 has not reached the target storage state (i.e., the erased state). Meanwhile, the difference between AF and BF (i.e., AF-BF) is set to an actual difference value Z, and the multiple value N and the ratio value R are adjusted according to the actual difference value Z (Step S458). Then, BF is set to be equal to AF (step S459), and step S452 is repeatedly done.

As mentioned above, the state change of the memory cell 100 before and after receiving the pulse will be determined, and then the pulse height or the pulse width of the next pulse will be dynamically adjusted according to the state change. An example of performing the pulse adjustment step S458 to adjust the pulse height will be described as follows. FIG. 4C schematically illustrates an implementation example of performing the pulse adjustment step S458 of FIG. 4B to adjust the pulse height.

The procedures of the pulse adjustment step S458 will be described as follows. Firstly, a step S462 is performed to judge whether the flag register 425 has been set. For example, if the initial value of the flag register 425 is “O”, it means that the flag register 425 has not been set. If the value stored in the flag register 425 is “1”, it means that the flag register 425 is set. In an embodiment, the pulse height of the pulse is sufficient when the flag register 425 is set. Subsequently, the fine-tuning of the pulse height is sufficient to allow the memory cell 100 to gradually reach the target storage state.

If the judging result of the step S462 indicates that the flag register 425 has not been set, a step S464 is performed to judge whether the actual difference value Z is less than a preset difference value X. If the judging result of the step S464 indicates that actual difference value Z is less than the preset difference value X, it means that the pulse height of the previous pulse is insufficient and the state of the memory cell 100 cannot be significantly changed. Then, the multiple value N is increased, and the ratio value R is increased (step S466). Consequently, the pulse height of the next pulse is increased.

If the judging result of the step S462 indicates that the flag register 425 has not been set and the judging result of the step S464 indicates that actual difference value Z is greater than or equal to the preset difference value X, it means that the pulse height of the previous pulse is sufficient to cause a significant change in the state of the memory cell 100. Subsequently, the fine-tuning of the pulse height is sufficient to allow the memory cell 100 to gradually reach the target storage state. Then, the flag register 425 is set (Step S468). After the step S468, a step S470 is performed to judge whether the actual difference value Z is equal to the preset difference value X. If the judging result of the step S470 indicates that the actual difference value Z is equal to the preset difference value X, the multiple value N is maintained, and the ratio value R is maintained (step S472). Whereas, if the judging result of the step S470 indicates that the actual difference value Z is greater than the preset difference value X, the multiple value N is maintained, and the ratio value R is decreased (Step S474).

In some other embodiments, the step S468 and the step S470 are swapped. That is, if the judging result of the step S470 indicates that the actual difference value Z is equal to the preset difference value X, the flag register 425 is set (Step S468), and then the step S472 is performed. Alternatively, if the judging result of the step S470 indicates that the actual difference value Z is greater than the preset difference value X, the flag register 425 is set (Step S468), and then the step S474 is performed. In addition, the step S468 and the step S472 can be combined into a single step. Similarly, the step S468 and the step S474 can be combined into a single step.

If the judging result of the step S462 indicates that the flag register 425 has been set, the pulse height of the next pulse is adjusted according to the actual difference value Z (step S480). If the actual difference value Z is less than the preset difference value X, the multiple value N is maintained, and the ratio value R is increased (Step S482). If the actual difference value Z is equal to the preset difference value X, the multiple value N is maintained, and the ratio value R is maintained (Step S484). If the actual difference value Z is greater than the preset difference value X, the multiple value N is maintained, and the ratio value R is decreased (step S486).

FIG. 4D is a schematic timing waveform diagram of the operation pulse signal to describe the implementation of the flowcharts of FIGS. 4B and 4C. In FIG. 4D, the reference voltage V_{REF} is 1.3V, the initial multiple value N is 12, the initial ratio value R is 0.9, and the preset difference value X is set to 2. In addition, the multiple value N is increases by 1 each time, and the ratio value R is increases or decreases by an offset O each time. For example, the offset O is equal to 0.025.

Please refer to FIG. 4D. Before the pulse generator 400 generates a first pulse P₁, i.e., before the time point t₁, a verification action is performed to confirm that the sub-state value of the memory cell 100 is 0 (i.e., the programmed state), and BF is set to 0. Then, according to the multiple value N (N=12) and the initial ratio value R (R=0.9), the pulse generator 400 generates the first pulse P₁ with a pulse height of 14.04V (12×0.9×1.3V) to the memory cell 100 in the time interval between the time point t₁ and the time point t₂. After the time point t₂, a verification action is performed again to confirm that the sub-state value of the memory cell 100 is 0, and AF is set equal to 0.

Since AF is equal to 0, the memory cell 100 has not reached the target storage state (i.e., the erased state), and the erase action has not ended. That is, the operation pulse generator 400 needs to adjust and generate a second pulse P₂ to the memory cell 100. Since the actual difference value Z is equal to 0, which is less than the preset difference value X (X=2), the multiple value N is increases by 1 (becomes N=13), and the ratio value R is increases by 0.025 (becomes R=0.925). In addition, BF is set to AF. Then, according to the multiple value N (N=13) and the ratio value R (R=0.925), the operation pulse generator 400 generates the second pulse P₂ with a pulse height of 15.6325V (13×0.925×1.3V) to the memory cell 100 in the time interval between the time point t₃ and the time point t₄. After the time point t₄, a verification action is performed to confirm that the sub-state value of the memory cell 100 is 0, and AF is set to 0.

Since AF is equal to 0, the memory cell 100 has not reached the target storage state (i.e., the erased state), and the erase action has not ended. That is, the operation pulse generator 400 needs to adjust and generate a third pulse P₃ to the memory cell 100. Since the actual difference value Z is equal to 0, which is less than the preset difference X (X=2), the multiple value N is increases by 1 (becomes N=14), and the ratio value R is increases by 0.025 (becomes R=0.95). In addition, BF is set to AF. Then, according to the multiple value N (N=14) and the ratio value R (R=0.95), the operation pulse generator 400 generates the third pulse P₃ with a pulse height of 17.29V (14×0.95×1.3V) to the memory cell 100 in the time interval between the time point t₅ and the time point to. After the time point to, a verification action is performed to confirm that the sub-state value of the memory cell 100 is 0, and AF is set to 0.

Since AF is equal to 0, the memory cell 100 has not reached the target storage state (i.e., the erased state), and the erase action has not ended. That is, the operation pulse generator 400 needs to adjust and generate a fourth pulse P₄ to the memory cell 100. Since the actual difference value Z is equal to 0, which is less than the preset difference value X (X=2), the multiple value N is increases by 1 (becomes N=15), and the ratio value R is increases by 0.025 (becomes R=0.975). In addition, BF is set equal to AF. Then, according to the multiple value N (N=15) and the ratio value R (R=0.975), the operation pulse generator 400 generates the fourth pulse P₄ with a pulse height of 19.0125V (15×0.975×1.3V) to the memory cell 100 in the time interval between the time point t₇ and the time point t₈. After the time point t₈, a verification action is performed to confirm that the sub-state value of the memory cell 100 is 3, and AF is set to 3.

Since AF is equal to 3, the memory cell 100 has not reached the target storage state (i.e., the erased state), and the erase action has not ended. That is, the operation pulse generator 400 needs to adjust and generate a fifth pulse P₅ to the memory cell 100. Since the actual difference value Z is equal to 3, which is greater than the preset difference value X (X=2), the flag register 425 is set (Flag=1). It means that an appropriate pulse height has been found, and only the pulse height needs to be fine-tuned in the future. Since the actual difference value Z is greater than the preset difference value X (Z>X), the multiple value N remains unchanged (N=15), and the ratio value R is decreased by 0.025 (becomes R=0.95). In addition, BF is set to AF. Then, according to the multiple value N (N=15) and the ratio value R (R=0.95), the operation pulse generator 400 generates the fifth pulse P₅ with a pulse height of 18.525V (15×0.95×1.3V) to the memory cell 100 in the time interval between the time point to and the time point t₁₀. After the time point t₁₀, a verification action is performed to confirm that the sub-state value of the memory cell 100 is 5, and AF is set to 5.

Since AF is equal to 5, the memory cell 100 has not reached the target storage state (i.e., the erased state), and the erase action has not ended. That is, the operation pulse generator 400 needs to adjust and generate a sixth pulse P₆ to the memory cell 100. Since the flag register 425 has been set (Flag=1) and the actual difference value Z is equal to the preset difference value X (X=2), the multiple value N remains unchanged (N=15), and the ratio value R remains unchanged (R=0.95). In addition, BF is set to AF. Then, according to the multiple value N (N=15) and the ratio value R (R=0.95), the operation pulse generator 400 generates the sixth pulse P₆ with a pulse height of 18.525V (15×0.95×1.3V) to the memory cell 100 in the time interval between the time point t₁₁ and the time point t₁₂. After the time point t₁₂, a verification action is performed to confirm that the sub-state value of the memory cell 100 is 6, and AF is set to 6.

Since AF is equal to 6, the memory cell 100 has not reached the target storage state (i.e., the erased state), and the erase action has not ended. That is, the operation pulse generator 400 needs to adjust and generate a seventh pulse P₇ to the memory cell 100. Since the flag register 425 has been set (Flag=1) and the actual difference value Z (equal to 1) is less than the preset difference value X (X=2), the multiple value N remains unchanged (N=15), and the ratio value R is increased (R=0.975). In addition, BF is set equal to AF. Then, according to the multiple value N (N=15) and the ratio value R (R=0.975), the operation pulse generator 400 generates the seventh pulse P₇ with the pulse height of 19.0125V (15×0.975×1.3V) to the memory cell 100 in the time interval between the time point t₁₃ and the time point t₁₄. After the time point t₁₄, a verification action is performed to confirm that the sub-state value of the memory cell 100 is 7, and AF is set to 7. It means that the memory cell 100 has reached the target storage state (i.e., the erased state). Consequently, the processor 420 activates the verification pass signal S_{PASS} to indicate that the erase action is completed. Then, the controller 430 stops generating the next pulse and ends the erase action.

As can be seen from the operation pulse signal P_{OP} in FIG. 4D, before the flag register 425 is set, the pulse heights of the pulses P₁-P₄ rise rapidly to search for an appropriate pulse height for the erase action. After the flag register 425 is set, the pulse heights of the pulses P₅-P₇ will be changed smoothly to allow the memory cell 100 to gradually reach the target storage state.

Of course, the pulse width in FIG. 4D can also be selectively adjusted according to the content of the flag register 425. For example, before the flag register 425 is set, the pulse width of the pulses P₁ to P₄ is narrower (e.g., 8 ms). After the flag register 425 is set, the pulse width of the pulses P₅ to P₇ is wider (e.g., 12 ms). In other words, after the flag register 425 of the processor 420 is set, the controller 430 further increases the pulse width of the subsequent pulses.

In accordance with the flowchart of FIG. 4C, the ratio value R is decreased in the step S474 and the step S486. In fact, an adjustment function of the ratio value R may also be set in this step. According to the adjustment function, the ratio value R can be increased or decreased.

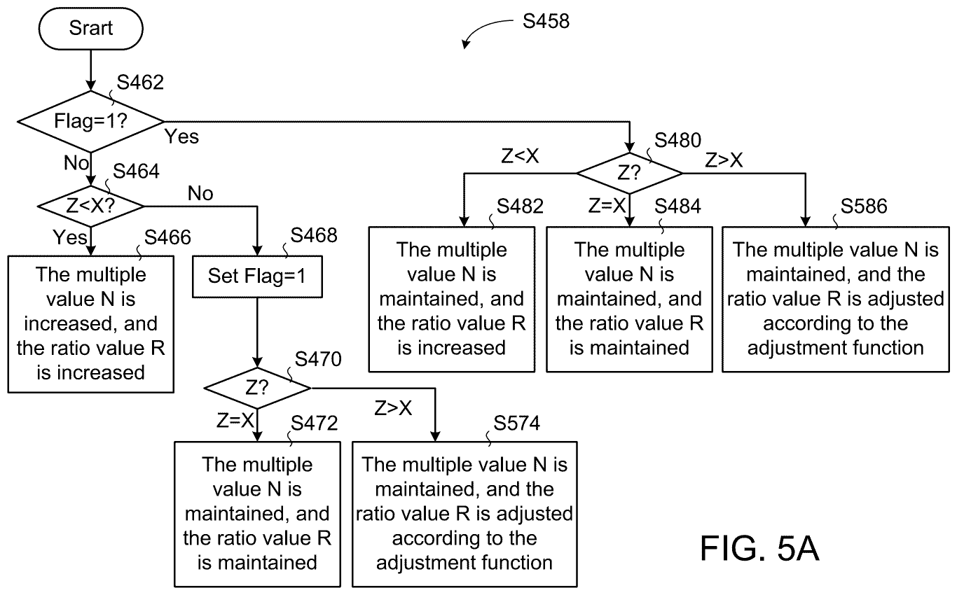

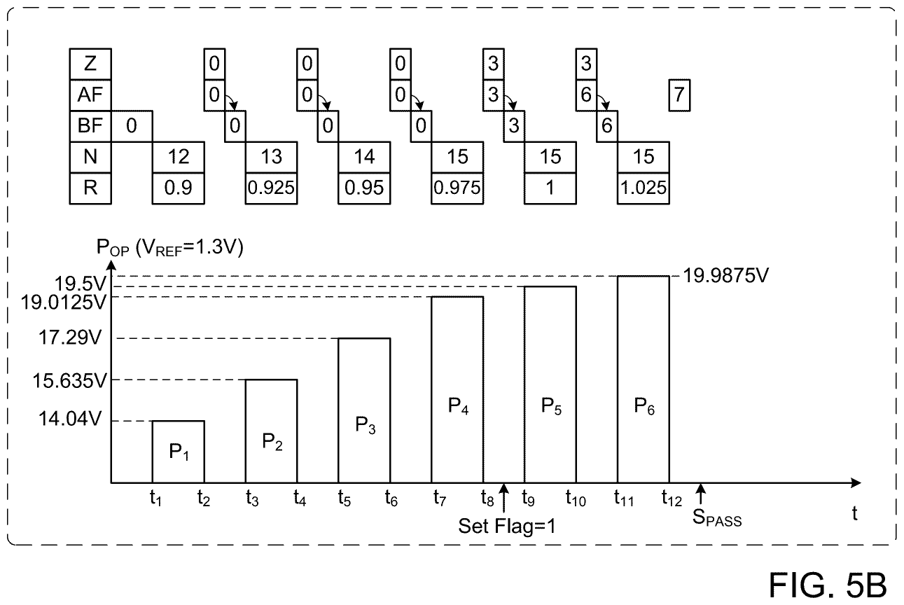

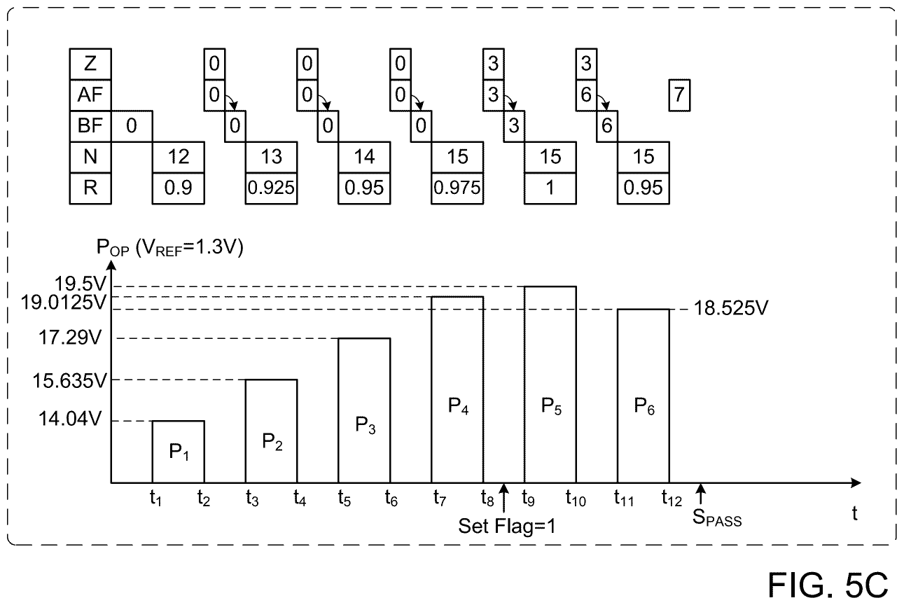

FIG. 5A schematically illustrates another implementation example of performing the pulse adjustment step S458 of FIG. 4B to adjust the pulse height. When compared with FIG. 4C, only the step S574 and the step S586 are distinguished. For succinctness, only the step S574 and the step S586 will be described as follows. The rest will not be redundantly described herein.

In the pulse adjustment step S458 of FIG. 5A, if the actual difference value Z is greater than the preset difference value X, the step S574 or the step S586 is performed. When the step S574 or the step S586 is performed, the multiple value N is maintained, and the ratio value R is corrected according to the adjustment function. Hereinafter, two implementation examples of using the adjustment function to generate the corresponding operation pulse signal P_{OP} during the erase action will be illustrated with reference to FIGS. 5B and 5C.

FIG. 5B is a schematic timing waveform diagram of the operation pulse signal to describe an implementation example of the flowcharts of FIGS. 4B and 5A. In FIG. 5B, the reference voltage V_{REF} is 1.3V, the initial multiple value N is 12, the initial ratio value R is 0.9, and the preset difference value X is set to 2. In addition, the multiple value N is increases by 1 each time, and the ratio value R is increases or decreases by an offset (i.e. an increment and a decrement of the ratio value R) O each time. For example, the offset O is equal to 0.025. In addition, the adjustment function of the ratio value R is expressed as: [R+ (Y−Z)×O]. According to the adjustment function, the corrected ratio value R is equal to the result of an preset adjustment parameter Y minus the actual difference value Z multiplied by the offset O plus the original ratio value R. In the above adjustment function, Y is the adjustment parameter, and the adjustment range of the ratio value R can be changed according to the adjustment parameter Y. For illustration, the adjustment parameter Y is equal to 4 in the following example, and the adjustment parameter Y can be preset in the design of the processor 420.

In FIG. 5B, the four pulses P₁ to P₄ before the time point t₈ are identical to those in FIG. 4D, and not redundantly described herein. Furthermore, after the time point t₈, a verification action is performed to confirm that the sub-state value of the memory cell 100 is 3, and AF is set to 3.

Since AF is equal to 3, the memory cell 100 has not reached the target storage state (i.e., the erased state), and the erase action has not ended. That is, the operation pulse generator 400 needs to adjust and generate a fifth pulse P₅ to the memory cell 100. Since the actual difference value Z is equal to 3, which is greater than the preset difference value X (X=2), the flag register 425 is set (Flag=1). It means that a suitable pulse height has been found, and only the pulse height needs to be fine-tuned in the future. Since the actual difference value Z is greater than the preset difference value X (Z>X), the multiple value N remains unchanged (N=15). According to the adjustment function, the corrected ratio value R is 1, i.e., [0.975+ (4−3)×0.025]=1. In addition, BF is set to AF. Then, according to the multiple value N (N=15) and the ratio value R (R=1), the operation pulse generator 400 generates the fifth pulse P₅ with the pulse height of 19.5V (15×1×1.3V) to the memory cell 100 in the time interval between the time point to and the time point t₁₀. After the time point t₁₀, a verification action is performed to confirm that the sub-state value of memory cell 100 is 6, and AF is set to 6.

Since AF is equal to 6, the memory cell 100 has not reached the target storage state (i.e., the erased state), and the erase action has not ended. That is, the operation pulse generator 400 needs to adjust and generate a sixth pulse P₆ to the memory cell 100. Since the flag register 425 has been set (Flag=1) and the actual difference value Z (equal to 3) is greater than the preset difference value X (X=2), the multiple value N remains unchanged (N=15). According to the adjustment function, the corrected ratio value R is 1.025, i.e., [1+ (4−3)×0.025]=1.025. In addition, BF is set to AF. Then, according to the multiple value N (N=15) and the ratio value R (R=1.025), the operation pulse generator 400 generates the sixth pulse P₆ with the pulse height of 19.9875V (15×1.025×1.3V) to the memory cell 100 in the time interval between the time point t₁₁ and the time point t₁₂. After the time point t₁₂, a verification action is performed to confirm that the sub-state value of the memory cell 100 is 7, and AF is set to 7. It means that the memory cell 100 has reached the target storage state (i.e., the erased state). Consequently, the processor 420 activates the verification pass signal S_{PASS} to indicate that the erase action is completed. Then, the controller 430 stops generating the next pulse and ends the erase action.

FIG. 5C is a schematic timing waveform diagram of the operation pulse signal to describe another implementation example of the flowcharts of FIGS. 4B and 5A. In FIG. 5C, the reference voltage V_{REF} is 1.3V, the initial multiple value N is 12, the initial ratio value R is 0.9, and the preset difference value X is set to 2. In addition, the multiple value N is increases by 1 each time, and the ratio value R is increases or decreases by an offset O each time. For example, the offset O is equal to 0.025. In addition, the adjustment function of the ratio value R is expressed as: [R+ (Y−Z)×O]. In addition, the adjustment parameter Y is equal to the difference between the target storage state value and the current sub-state, i.e., Y=(7−AF).

In FIG. 5C, the four pulses P₁ to P₄ before the time point t₈ are identical to those in FIG. 4D, and not redundantly described herein. Furthermore, after the time point t₈, a verification action is performed to confirm that the sub-state value of the memory cell 100 is 3, and AF is set to 3.

Since AF is equal to 3, the memory cell 100 has not reached the target storage state (i.e., the erased state), and the erase action has not ended. That is, the operation pulse generator 400 needs to adjust and generate a fifth pulse P₅ to the memory cell 100. Since the actual difference value Z (equal to 3) is greater than the preset difference value X (X=2), the flag register 425 is set (Flag=1). It means that a suitable pulse height has been found, and only the pulse height needs to be fine-tuned in the future. Since the actual difference value Z is greater than the preset difference value X (Z>X), the multiple value N remains unchanged (N=15). According to the adjustment function, the corrected ratio value R is 1, i.e., {0.975+ [(7−3)-3]×0.025}=1. In addition, BF is set to AF. Then, according to the multiple value N (N=15) and the ratio value R (R=1), the operation pulse generator 400 generates the fifth pulse P₅ with the pulse height of 19.5V (15×1×1.3V) to the memory cell 100 in the time interval between the time point to and the time point t₁₀. After the time point t₁₀, a verification action is performed to confirm that the sub-state value of memory cell 100 is 6, and AF is set to 6.

Since AF is equal to 6, the memory cell 100 has not reached the target storage state (i.e., the erased state), and the erase action has not ended. That is, the operation pulse generator 400 needs to adjust and generate a sixth pulse P₆ to the memory cell 100. Since the flag register 425 has been set (Flag=1) and the actual difference value Z (equal to 3) is greater than the preset difference value X (X=2), the multiple value N remains unchanged (N=15). According to the adjustment function, the corrected ratio value R is 0.95, i.e., {1+ [(7−6)−3]×0.025}=0.95. In addition, BF is set to AF. Then, according to the multiple value N (N=15) and the ratio value R (R=0.95), the operation pulse generator 400 generates the sixth pulse P₆ with the pulse height of 18.525V (15×0.95×1.3V) to the memory cell 100 in the time interval between the time point t₁₁ and the time point t₁₂. After the time point t₁₂, a verification action is performed to confirm that the sub-state value of the memory cell 100 is 7, and AF is set to 7. It means that the memory cell 100 has reached the target storage state (i.e., the erased state). Consequently, the processor 420 activates the verification pass signal S_{PASS} to indicate that the erase action is completed. Then, the controller 430 stops generating the next pulse and ends the erase action.

Obviously, the operation pulse signal control method shown in FIG. 5B or FIG. 5C can use fewer pulses to complete the erase action and allow the memory cell 100 to reach the erasing state. Consequently, the erasing efficiency is enhanced. Furthermore, the control method shown in FIG. 4B, FIG. 4C or FIG. 5A can be applied to the program action. The operating principles will not be redundantly described herein.

According to the embodiment of the present invention, when a new action is started, the processor 420 provides an initial multiple value N and an initial ratio value R to the controller 430 to generate the first pulse P₁. In fact, an initial multiple value N and an initial ratio value R of a new action can be determined by the processor 420 according to the final multiple value N and the ratio value R of the previous action. Take FIG. 4D as an example. When the processor 420 provides the multiple value N (N=15) and the ratio value R (R=0.975) to the controller 430, the operation pulse generator 400 generates the last pulse (the seventh pulse P₇) to the memory cell 100. Afterwards, the processor 420 activates the verification pass signal S_{PASS} to indicate that the erase action is completed. Then, the controller 430 stops generating the next pulse and ends the erase action. At this time, the multiple value N (N=15) and the ratio value R (R=0.975) are the final multiple value N and the final ratio value R of this action.

When a new erase action or a new program action is started, the processor 420 may determine an initial multiple value N and an initial ratio value R according the final multiple value N and the final ratio value R of the previous action. For example, an adjusting value T set in the processor 420 is (−1). Then, the initial multiple value N is 14, that is, [15+ (T)=15−1]; and the initial value R is 0.95, that is, [0.975+(T)×(0.025)=0.975−0.025]. The value 0.0025 is the offset O. Alternatively, the adjustment value T may be set to zero. Thus, the initial value N is 15 (15+0); and the initial value R is 0.975 (0.976+0×0.025).

It is noted that the application of the operation pulse signal control method of the present invention is not restricted to the 3T2C memory cell 100 shown in FIG. 1A. That is, the operation pulse signal control method of the present invention can be applied to any other appropriate memory cell. For example, when the program action is performed, the first terminal of a specific structure memory cell receives a fixed program voltage, and the program voltage is the highest bias voltage. Under this circumstance, the operation pulse signal P_{OP} can be used to replace the program voltage and inputted into the specific structure memory cell, and the operation pulse signal control method of the present invention can be used to perform the program action on the specific structure memory cell. Similarly, when the erase action is performed, the second terminal of the specific structure memory cell receives a fixed erased voltage, and the erased voltage is the highest bias voltage. Under this circumstance, the operation pulse signal P_{OP} can be used to replace the erase voltage and inputted into the specific structure memory cell, and the operation pulse signal control method of the present invention can be used to perform the erase action on the specific structure memory cell.

From the above descriptions, the present invention provides an operation pulse signal control method for non-volatile memory cells. In accordance with the control method of the present invention, the state change of the memory cell before and after receiving the pulse will be determined, and then the pulse height or the pulse width of the next pulse will be dynamically adjusted according to the state change. Consequently, the programming efficiency and the erasing efficiency will be enhanced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An operation pulse signal control method for a non-volatile memory cell, the memory cell having plural sub-states corresponding to the amount of the electrons stored in the memory cell, the operation pulse signal control method comprising steps of:
(a) performing a verification action to obtain a first sub-state value of the memory cell;
(b) providing a pulse of an operation pulse signal to the memory cell;
(c) performing the verification action to obtain a second sub-state value of the memory cell;
(d) if the second sub-state value indicates that the memory cell has not reached a target storage state, defining an actual difference value as the second sub-state value minus the first sub-state value, generating a next pulse according to the actual difference value, setting the first sub-state value equal to the second sub-state value, and performing the step (b) again; and
(e) if the second sub-state value indicates that the memory cell has reached the target storage state, stopping providing the next pulse.

2. The operation pulse signal control method as claimed in claim 1, wherein when a program action is performed on the memory cell, the target storage state is a programmed state of the memory cell, when an erase action is performed on the memory cell, the target storage state is an erased state of the memory cell.

3. The operation pulse signal control method as claimed in claim 1, wherein the step (d) further comprises adjusting a pulse width or a pulse height of the next pulse according to the actual difference value.

4. The operation pulse signal control method as claimed in claim 1, wherein the step (b) further comprises a step of generating the pulse of the operation pulse signal to the memory cell according to a multiple value and a ratio value, wherein a pulse height of the pulse is equal to a multiplication result of the multiple value, the ratio value and a reference voltage.

5. The operation pulse signal control method as claimed in claim 4, wherein the step (d) further comprises steps of:
(d1) if a flag register has not been set and the actual difference value is less than a preset difference value, increasing the multiple value, and increasing the ratio value;
(d2) if the flag register has not been set and the actual difference value is equal to the preset difference value, setting the flag register, maintaining the multiple value, and maintaining the ratio value; and
(d3) if the flag register has not been set and the actual difference value is greater than the preset difference value, setting the flag register, maintaining the multiple value, and decreasing the ratio value.

6. The operation pulse signal control method as claimed in claim 5, wherein the step (d) further comprises steps of:
(d4) if the flag register has been set and the actual difference value is less than the preset difference value, maintaining the multiple value, and increasing the ratio value;
(d5) if the flag register has been set and the actual difference value is equal to the preset difference value, maintaining the multiple value, and maintaining the ratio value; and
(d6) if the flag register has been set and the actual difference value is greater than the preset difference value, maintaining the multiple value, and decreasing the ratio value.

7. The operation pulse signal control method as claimed in claim 4, wherein the step (d) further comprises steps of:
(d1) if a flag register has not been set and the actual difference value is less than a preset difference value, increasing the multiple value, and increasing the ratio value;
(d2) if the flag register has not been set and the actual difference value is equal to the preset difference value, setting the flag register, maintaining the multiple value, and maintaining the ratio value;
(d3) if the flag register has not been set and the actual difference value is greater than the preset difference value, setting the flag register, maintaining the multiple value, and generating the ratio value according to an adjustment function;
(d4) if the flag register has been set and the actual difference value is less than the preset difference value, maintaining the multiple value, and increasing the ratio value;
(d5) if the flag register has been set and the actual difference value is equal to the preset difference value, maintaining the multiple value, and maintaining the ratio value; and
(d6) if the flag register has been set and the actual difference value is greater than the preset difference value, maintaining the multiple value, and generating the ratio value according to the adjustment function.

8. The operation pulse signal control method as claimed in claim 7, wherein according to the adjustment function, the corrected ratio value is expressed as: [R+(Y−Z)×O], wherein R is the ratio value, Y is an adjustment parameter, Z is the actual difference value, and O is an increment and a decrement of the ratio value.

9. The operation pulse signal control method as claimed in claim 8, wherein the adjustment parameter is equal to a target storage state value minus the second sub-state value.

10. The operation pulse signal control method as claimed in claim 1, wherein the memory cell comprises:
a select transistor, wherein a first source/drain terminal of the select transistor is connected to a source line, and a gate terminal of the select transistor is connected to a select gate line;
a floating gate transistor, wherein a first source/drain terminal of the floating gate transistor is connected to a second source/drain terminal of the select transistor;
a switch transistor, wherein a first source/drain terminal of the switch transistor is connected to a second source/drain terminal of the floating gate transistor, a second source/drain terminal of the switch transistor is connected to a bit line, and a gate terminal of the switch transistor is connected to a word line;
a first capacitor, wherein a first terminal of the first capacitor is connected to a floating gate of the floating gate transistor, and a second terminal of the first capacitor is connected to a control line; and
a second capacitor, wherein a first terminal of the second capacitor is connected to the floating gate of the floating gate transistor, and a second terminal of the second capacitor is connected to an erase line.

11. The operation pulse signal control method as claimed in claim 10, wherein when a program action is performed, a ground voltage is provided to the source line and the bit line, a turn-on voltage is provided to the word line and the select gate line, and the operation pulse signal is provided to the control line and the erase line.

12. The operation pulse signal control method as claimed in claim 10, wherein when an erase action is performed, a ground voltage is provided to the source line, the bit line and the control line, a turn-on voltage is provided to the word line and the select gate line, and the operation pulse signal is provided to the erase line.

13. The operation pulse signal control method as claimed in claim 10, wherein when the verification action is performed, the ground voltage is provided to the source line, a read voltage is provided to the bit line, a turn-on voltage is provided to the word line and the select gate line, and an operating voltage is provided to the erase line and the control line, wherein a storage state of the memory cell is determined as the first sub-state value or the second sub-state value according to the operating voltage and a cell current generated by the memory cell.

14. The operation pulse signal control method as claimed in claim 1, wherein the operation pulse signal is generated by an operation pulse generator, and the operation pulse generator comprises:
a bandgap reference circuit providing a reference voltage;
a processor receiving a sub-state signal to confirm the first sub-state value or the second sub-state value of the memory cell, wherein the processor provides a multiple value and a ratio value according to the first sub-state value and the second sub-state value; and
a controller receiving the reference voltage, the ratio value and the multiple value, and generating the next pulse of the operation pulse signal, wherein a pulse height of the next pulse is equal to a multiplication result of the multiple value, the ratio value and the reference voltage,
wherein the processor selectively activates a verification pass signal according to the sub-state signal,
wherein if the verification pass signal is activated, the controller stops providing the next pulse.

15. The operation pulse signal control method as claimed in claim 14, wherein the processor further comprises a flag register, wherein when the flag register is set, a pulse width of the next pulse is increased.
